(19) United States
(12) Patent Application Publication
(10) Pub. No.: US 2007/0218681 A1
(43) Pub. Date: Sep. 20, 2007

(54) PLASMA ETCHING METHOD AND COMPUTER-READABLE STORAGE MEDIUM

(75) Inventor: Ryoichi YOSHIDA, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/686,746

(22) Filed: Mar. 15, 2007

Related U.S. Application Data
(60) Provisional application No. 60/785,995, filed on Mar. 27, 2006.

(30) Foreign Application Priority Data
Mar. 16, 2006 (JP) 2006-072826

(51) Int. Cl. H01L 21/465

(52) U.S. Cl. 438/638; 438/710

(57) ABSTRACT

A plasma etching method for forming a trench on a substrate or on a film formed on the substrate, includes an substrate arranging step of arranging the substrate on which the trench is to be formed in a processing chamber having therein a first and a second electrode disposed to face each other vertically; a processing gas introducing step of introducing a processing gas for etching into the processing chamber; a plasma generating step of generating a plasma by applying a high frequency electric power to either of the first and the second electrode; and a DC voltage applying step of applying a DC voltage to said either of the electrodes. Further, a computer-readable storage medium stores therein a computer-executable control program, wherein, when the control program is being executed, a computer is made to control a plasma processing apparatus to perform the plasma etching method.

### FIELD OF THE INVENTION

The present invention relates to a plasma etching method and a computer-readable storage medium for forming a trench on a substrate or on a film formed thereon such as an interlayer insulating film.

### BACKGROUND OF THE INVENTION

In a semiconductor device, a miniaturization reduces a distance between wirings, and this causes an increase in an inter-wiring capacitance. Therefore, a signal propagation speed is reduced, thereby deteriorating an operating speed. To solve the above problem, an insulating material having a low dielectric constant (low-k material) has been recently used as an interlayer insulating film. Further, copper, which has low resistance and high electromigration tolerance, has been noticed as a wiring material. Furthermore, a dual damascene method is often used to form a connecting opening or a groove wiring of copper.

When a multilayer interconnection of copper is formed by using the dual damascene method, firstly, an etching stop film is formed on an underlying copper wiring. Next, a low-k film serving as an interlayer insulating film, a metal hard mask layer, a bottom anti-reflection coating (BARC) and a photoresist film are formed thereon in this order. Thereafter, a via is formed by etching the low-k film and, then, an etching of a trench is performed. Subsequently, the via is penetrated by etching the etching stop film and, then, a buried wiring layer of Cu is formed.

Recently, in a high-integration power IC with integrated power MOSFETs, there has been proposed a trench lateral power MOSFET having a trench formed on a silicon substrate (semiconductor wafer) and an extended drain region arranged inside the trench. The trench lateral power MOSFET can control the extended drain region, required for a pressure resistance, to be of a depth of trench, and thus can reduce an on-resistance per unit area compared with a conventional power MOSFET that has an extended drain region on a surface of a silicon substrate.

Since a trench formed in the low-k film has a direct effect on a thickness of a wiring, and a trench formed in the silicon substrate for the extended drain directly affects a pressure resistance, the etching uniformity is extremely important in both cases. However, when these trenches are formed, it is not possible to stop the etching by different kinds of films, so that the etching depth is likely to be formed unevenly. Hence, when the trenches are etched, it is important to uniformly control an etching rate in a surface of a semiconductor wafer.

Conventionally, a plasma etching has been performed mainly by a capacitively coupled parallel plate type plasma etching apparatus. The capacitively coupled parallel plate type plasma etching apparatus has a chamber with a pair of parallel plate electrodes (upper and lower electrode). While a processing gas is introduced into the chamber, a high frequency is applied to either of the electrodes to form a high frequency electric field between the electrodes. The processing gas is turned into a plasma by the high frequency electric field, thereby performing a plasma etching on a specific layer disposed on a semiconductor wafer.

To be specific, there has been known a plasma etching apparatus for forming a plasma by applying a high frequency power for plasma generation to an upper electrode and then obtaining a desired plasma state by applying a high frequency power for ion attraction to a lower electrode (see, e.g., Patent Document 1).

When the etching is performed by the capacitively coupled parallel plate type plasma etching apparatus by using an electronegative gas such as CF₄ or the like, a plasma density and an etching rate in a central portion of a semiconductor wafer tends to be decreased. For this reason, the etching rate is controlled by adjusting parameters such as an inner pressure of the chamber, an applied power from a high frequency power supply and the like to thereby achieve an etching uniformity throughout the surface.

If the etching uniformity is controlled by conventional parameters, the etching rate in the central portion can be reduced. However, since an etching rate in other portions is also changed, the etching rate distribution becomes W-shaped or M-shaped, making it difficult to obtain the etching uniformity required for the trench etching. Moreover, although a low power etching is desired in the trench etching, the etching rate is difficult to be controlled by adjusting the conventional parameters in the low power etching process.

(Patent Document 1) Japanese Patent Publication Application No. 2000-173993

### SUMMARY OF THE INVENTION

It is, therefore, an object of the present invention to provide a plasma etching method capable of performing a trench etching on a substrate or on a film formed thereon with high intra-surface uniformity even when using a high frequency power.

Further, it is another object of the present invention is to provide a computer-readable storage medium for storing therein a program for implementing the plasma etching method.

In accordance with one aspect of the invention, there is provided a plasma etching method for forming a trench on a substrate or on a film formed on the substrate, including an substrate arranging step of arranging the substrate on which the trench is to be formed in a processing chamber having therein a first and a second electrode disposed to face each other vertically; a processing gas introducing step of introducing a processing gas for etching into the processing chamber; a plasma generating step of generating a plasma by applying a high frequency electric power to either of the first and the second electrode; and a DC voltage applying step of applying a DC voltage to said either of the electrodes.

In this case, it is preferable that the DC voltage is within a range from about −400 V to about −1500 V. Further, the trench may be formed in an interlayer insulating film formed on the substrate. Also, the trench may be formed after forming a via in the interlayer insulating film. Moreover, when the DC voltage is applied to either of the electrodes, the DC voltage may have a previously obtained value for ensuring desired etching uniformity in a test target substrate. In addition, the first and the second electrode may be an upper electrode and a lower electrode for mounting thereon the target substrate, respectively, and the DC voltage and the high frequency power for plasma generation may be applied to the first electrode. In this case, a high frequency power for ion attraction may be applied to the second electrode.

In accordance with another aspect of the invention, there is provided a computer-readable storage medium for storing therein a computer-executable control program, wherein, when the control program is being executed, a computer is made to control a plasma processing apparatus to perform the above-mentioned plasma etching method.

In accordance with the present invention, when the trench is formed on the substrate or on the film thereon such as the interlayer insulating film or the like, a plasma is generated by applying a high frequency power to either of the first and the second electrode. Further, a DC voltage is also applied to either of the electrodes, so that the plasma is also generated by the DC voltage. Accordingly, a plasma density is increased to thereby enhance the etching rate. In this case, even when using a high frequency power, the plasma density in the central portion can be relatively increased to promote a plasma diffusion. Hence, even if an etching gas is an electronegative gas, the etching rate can be increased in the central portion where the plasma density tends to be low in case an etching gas is an electronegative gas, so that a uniform etching can be performed.

### BRIEF DESCRIPTION OF THE DRAWINGS

The above and other objects and features of the present invention will become apparent from the following description of an embodiment, given in conjunction with the accompanying drawings, in which:

FIG. 1 is a schematic cross sectional view of an example of a plasma etching apparatus used for implementing the present invention;

FIG. 2 shows a structure of a matching unit connected to a first high frequency power in the plasma etching apparatus of FIG. 1;

FIG. 3 illustrates a cross sectional view showing a state in which a partial via has been formed by an etching on a semiconductor wafer W in accordance with an embodiment of the present invention;

FIG. 4 presents a cross sectional view illustrating a structure of a semiconductor wafer where a BARC and a photoresist film has been ashed for a trench etching after forming the partial via of FIG. 3;

FIG. 5 represents a cross sectional view illustrating a state in which a trench has been formed by etching an interlayer insulating film in accordance with the embodiment of the present invention;

FIG. 6 describes examples of the intra-surface distribution of etching rate of an oxide film when different DC voltages are applied;

FIG. 7 depicts other example of the intra-surface distribution of etching rate of the oxide film when different DC voltages are applied;

FIG. 8 shows locations on a semiconductor wafer where a trench depth has been measured after performing the trench etching;

FIG. 9 offers a schematic cross sectional view of an example of another plasma etching apparatus that can be employed for implementing the present invention;

FIG. 10 provides a schematic cross sectional view of an example of still another plasma etching apparatus that can be employed for implementing the present invention;

FIG. 11 illustrates a schematic cross sectional view of an example of still another plasma etching apparatus that can be employed for implementing the present invention; and

FIG. 12 depicts a schematic cross sectional view of an example of still another plasma etching apparatus that can be employed for implementing the present invention.

### DETAILED DESCRIPTION OF THE EMBODIMENT

Hereinafter, an embodiment of the present invention will be described in detail with reference to the accompanying drawings.

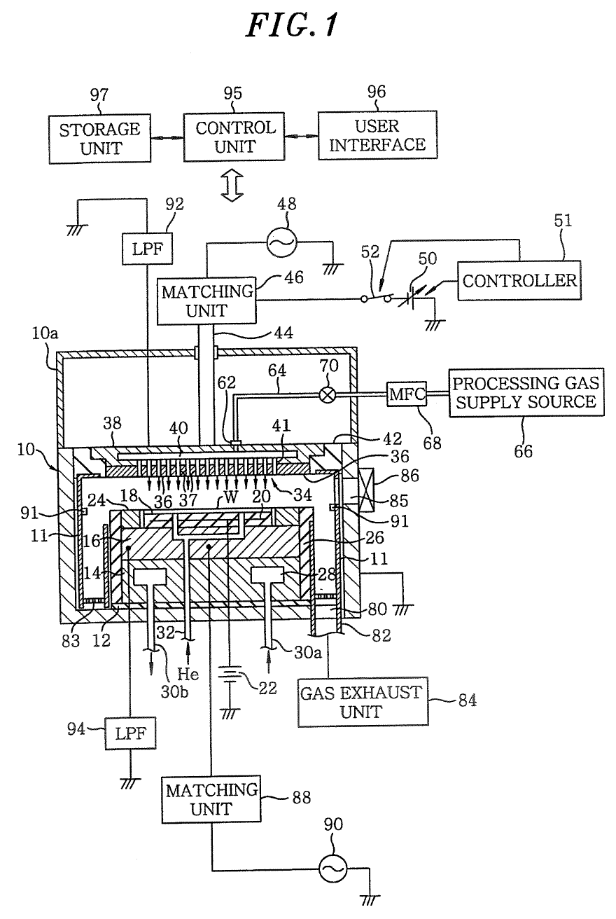

FIG. 1 is a schematic view showing one example of a plasma etching apparatus utilized in implementing the present invention.

This plasma etching apparatus is a capacitance-coupled parallel plate type plasma etching apparatus and includes a generally cylindrical chamber (processing chamber) 10 made of, e.g., surface-anodized aluminum. The chamber 10 is a frame-grounded.

On a bottom portion of the chamber 10, there is arranged a cylindrical susceptor base 14 through an insulating plate 12 made of ceramics or other materials. A susceptor 16 made of, e.g., aluminum, is provided on the susceptor base 14, wherein the susceptor 16 is adapted to serve also as a lower electrode. A semiconductor wafer W serving as an object substrate is mounted on the susceptor (lower electrode) 16.

On a top surface of the susceptor 16, there is provided an electrostatic chuck 18 that attracts and holds the semiconductor wafer W with an electrostatic force. The electrostatic chuck 18 is of a structure having an electrode 20 made of a conductive film and interlaid between a pair of insulating layers or insulating sheets. A direct current power supply 22 is electrically connected to the electrode 20. The semiconductor wafer W is attracted to and held in place on the electrostatic chuck 18 by virtue of an electrostatic force, such as the Coulomb force, generated by a direct current voltage supplied from the direct current power supply 22.

On the top surface of the susceptor 16 around the electrostatic chuck 18 (or the semiconductor wafer W), there is arranged a focus ring (calibration ring) 24 that is made of, e.g., silicon, and serves to improve an etching uniformity. A cylindrical inner wall member 26 made of, e.g., quartz, is provided on the outer surface of the susceptor 16 and the susceptor base 14.

A coolant chamber 28 is formed within the susceptor base 14 to extend, e.g., annularly along a circumferential direction. Coolant, e.g., cooling water, of a predetermined temperature is supplied to the coolant chamber 28 from an external chiller unit (not shown) to be circulated therein through pipelines 30a and 30b. The temperature at which the semiconductor wafer W on the susceptor 16 is treated can be controlled based on the temperature of the coolant.

Furthermore, a heat-conductive gas, e.g., an He gas, is supplied from a heat-conductive gas supply mechanism (not shown) to a space formed between a top surface of the electrostatic chuck 18 and a back surface of the semiconductor wafer W through a gas supply line 32.

Above the lower electrode or susceptor 16, there is provided an upper electrode 34 in a parallel and mutually facing relationship with the susceptor 16. Thus, the space formed between the upper electrode 34 and the lower electrode 16 becomes a plasma generation space. The upper electrode 34 is adapted to face the semiconductor wafer W on the lower electrode or susceptor 16, thereby forming a surface contiguous to the plasma generation space, i.e., an opposing surface.

The upper electrode 34 is supported on an upper portion of the chamber 10 through an insulating shield member 42 and is constructed from an electrode plate 36 and a water-cooled electrode support body 38. The electrode plate 36 forms a surface facing the susceptor 16 and has a plurality of ejection ports 37. The electrode support body 38 is adapted to detachably support the electrode plate 36 and is made of a conductive material, e.g., surface-anodized aluminum. The electrode plate 36 is preferably formed of a conductive body with a small Joule heat and a low resistance or a semiconductor. From a standpoint of reinforcing a resist as set forth below, it is preferred that the electrode plate 36 be formed of a silicon-containing material. Thus, the electrode plate 36 is preferably made of silicon or SiC. Inside the electrode support body 38, there is provided a gas diffusion chamber 40 from which a multiple number of gas passage holes 41 extend in a downward direction to communicate with gas ejection ports 37.

The electrode support body 38 has a gas inlet port 62 through which a processing gas is led to the gas diffusion chamber 40. Connected to the gas inlet port 62 is a gas supply conduit 64 which in turn is associated with a processing gas supply source 66. A mass flow controller (MFC) 68 and a shutoff valve 70 are provided on the gas supply conduit 64 in the named sequence from the upstream side (an FCS (Flow Control System) may be used in place of the MFC). The processing gas for an etching operation, e.g., a fluorocarbon gas (CₓF_{y}) such as a CF₄ gas, is supplied to the gas diffusion chamber 40 from the processing gas supply source 66 through the gas supply conduit 64 and then is ejected into the plasma generation space in the form of a shower through the gas passage holes 41 and the gas ejection ports 37. Namely, the upper electrode 34 serves to function also as a shower head for supplying the processing gas.

A first high-frequency power supply 48 is electrically connected to the upper electrode 34 via a matching unit 46 and a power supply rod 44. The first high-frequency power supply 48 is adapted to generate a high frequency power with a frequency of 10 MHz or higher, e.g., 60 MHz. The matching unit 46 serves to match a load impedance to an internal (output) impedance of the first high-frequency power supply 48 and functions to ensure that the apparent output impedance of the first high-frequency power supply 48 coincide with the apparent load impedance while plasma is being generated within the chamber 10. The matching unit 46 has an output terminal connected to a top end of the power supply rod 44.

In the meantime, a variable direct current power supply 50 as well as the first high-frequency power supply 48 is electrically connected to the upper electrode 34. The variable direct current power supply 50 may be a bipolar power supply. More specifically, the variable direct current power supply 50 is connected to the upper electrode 34 via the matching unit 46 and the power supply rod 44, and the power supply operation of the variable direct current power supply 50 is turned on or off by means of an on-off switch 52. A controller 51 is employed to control the polarity, current and voltage of the variable direct current power supply 50 and the on-off operation of the on-off switch 52.

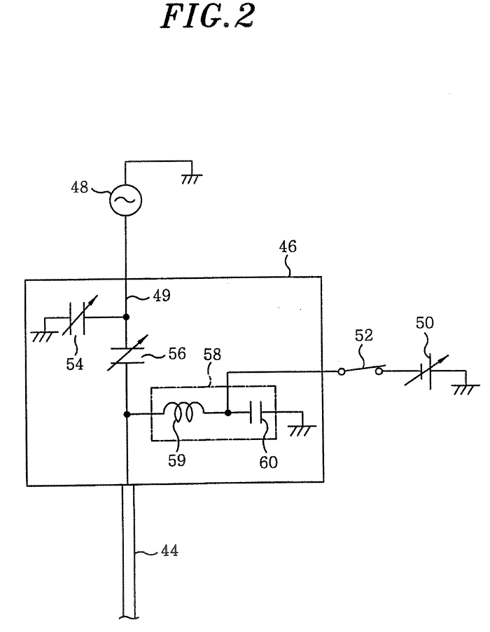

Referring to FIG. 2, the matching unit 46 includes a first variable capacitor 54 branched from a power supply line 49 of the first high-frequency power supply 48 and a second variable capacitor 56 provided on the power supply line 49 downstream of the branching point of the first variable capacitor 54, both of which cooperate to perform the function noted above. In order to assure effective supply of an electric current of direct current voltage (hereinbelow simply referred to as “direct current voltage”) to the upper electrode 34, the matching unit 46 further includes a filter 58 for trapping the high frequency (of, e.g., 60 MHz) from the first high-frequency power supply 48 and the high frequency (of, e.g., 2 MHz) from a below-mentioned second high-frequency power supply. In other words, a direct current is supplied from the variable direct current power supply 50 to the power supply line 49 via the filter 58. The filter 58 includes a coil 59 and a capacitor 60, both of which serve to trap the high frequency from the first high-frequency power supply 48 and the high frequency from the below-mentioned second high-frequency power supply.

A cylindrical grounding conductor 10a is provided to extend from the sidewall of the chamber 10 more upwardly than the elevation of the upper electrode 34. The cylindrical grounding conductor 10a has a ceiling wall portion electrically insulated from the power supply rod 44 by virtue of an insulating member 44a.

A second high-frequency power supply 90 is electrically connected to the lower electrode or susceptor 16 through a matching unit 88. As a high frequency power is supplied from the second high-frequency power supply 90 to the lower electrode or susceptor 16, ions are introduced toward the semiconductor wafer W. The second high-frequency power supply 90 is adapted to generate a high frequency power whose frequency is in the range between 300 kHz and 13.56 MHz, e.g., 2 MHz. The matching unit 88 serves to match a load impedance to an internal (output) impedance of the second high-frequency power supply 90 and functions to ensure that the output impedance of the second high-frequency power supply 90 coincides with the apparent load impedance while plasma is being generated within the chamber 10.

Electrically connected to the upper electrode 34 is a low-pass filter (LPF) 92 not allowing the high frequency (60 MHz) supplied from the first high-frequency power supply 48 from passing thereto while allowing the high frequency (2 MHz) supplied from the second high-frequency power supply 90 to pass to the ground. Although the low-pass filter 92 is preferably formed of an LR filter or an LC filter, use of a single conductor line may suffice because it would be able to apply a great enough reactance against the high frequency (60 MHz) supplied from the first high-frequency power supply 48. On the other hand, a high-pass filter (HPF) 94 for passing the high frequency (60 MHz) supplied from the first high-frequency power supply 48 to the ground is electrically connected to the lower electrode or susceptor 16.

An exhaust port 80 is provided on the bottom portion of the chamber 10 and a gas exhaust unit 84 is connected to the exhaust port 80 through an exhaust conduit 82. The gas exhaust unit 84 is provided with a vacuum pump such as a turbo molecular pump and is capable of depressurizing the inside of the chamber 10 to a desired level of vacuum. A gateway 85 through which the semiconductor wafer W is conveyed into or out of the chamber 10 is formed on the sidewall of the chamber 10. The gateway 85 is openably closed by means of a gate valve 86. A deposition shield 11 for preventing etching byproducts (depositions) from adhering to the chamber 10 is detachably provided along an inner wall of the chamber 10. That is to say, the deposition shield 11 forms a chamber wall. Another deposition shield 11 is provided on an outer circumference of the inner wall member 26. An exhaust plate 83 is provided near the lower portion of the chamber 10 between the deposition shield 11 closer to the chamber wall and the deposition shield 11 closer to the inner wall member 26. The deposition shields 11 and the exhaust plate 83 are preferably made of an aluminum material coated with ceramics such as Y₂O₃.

A conductive member (GND block) 91 grounded in a DC-like manner is provided on a portion of the deposition shield 11 for forming the chamber wall substantially at the same elevation as that of the semiconductor wafer W. This provides an advantageous effect that an abnormal electric discharge can be avoided.

Individual component parts of the plasma etching apparatus are configured such that they can be connected to and controlled by a control unit (general control device) 95. Also connected to the control unit 95 is a user interface 96 that includes, among other things, a keyboard for enabling a process manager to input commands to thereby manage the plasma etching apparatus and a display for visually displaying operating status of the plasma etching apparatus.

Additionally connected to the control unit 95 is a storage unit 97 that stores a control program for performing various processes executed by the plasma etching apparatus under a control of the control unit 95 and a program, i.e., recipes, for making the individual component parts of the plasma etching apparatus perform their tasks in accordance with given process conditions. The recipes may be stored in a hard disk or a semiconductor memory or may be set into a predetermined position of the storage unit 97 in a state recorded on a portable and computer-readable storage medium such as a CD-ROM, a DVD or the like.

If necessary, an arbitrary recipe is retrieved from the storage unit 97 by a command inputted through the user interface 96 and is then executed by the control unit 95, thus ensuring that a desired process is performed in the plasma etching apparatus under a control of the control unit 95.

The following is an explanation of a plasma etching method in accordance with an embodiment of the present invention which is implemented by using the plasma etching apparatus configured as described above.

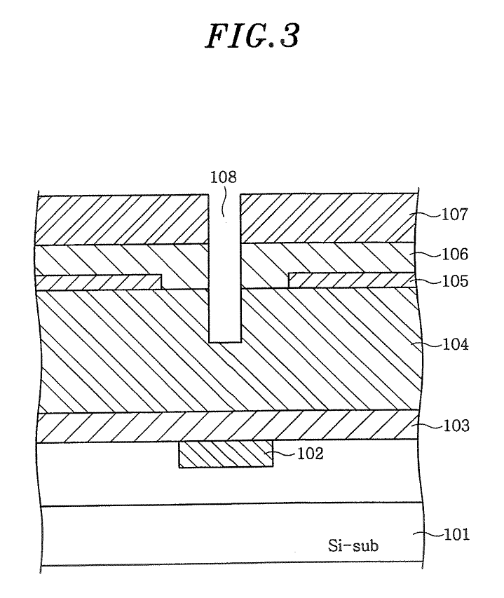

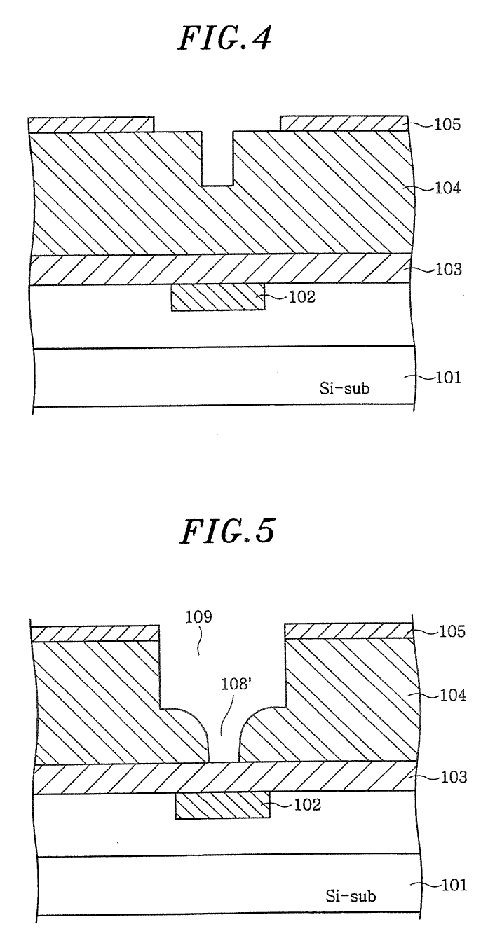

As shown in FIG. 3, as for a semiconductor wafer W serving as a target substrate, there is used one in which a copper wiring layer 102, an etching stop film 103, an interlayer insulating film 104, a metal hard mask layer 105 patterned for trench etching, a BARC 106 and a photoresist film 107 are formed in order on an Si substrate 101. Next, as shown in FIG. 3, a partial via 108 is formed by etching the BARC 106 and the interlayer insulting film 104 to an intermediate depth of the interlayer insulating film 104 while using the photoresist film 107 as an etching mask. Thereafter, the photoresist film 107 and the BARC 106 are removed by an etching to thereby the state shown in FIG. 3 is changed into the state shown in FIG. 4. Then, a trench etching is performed by using the metal hard mask layer 105 as an etching mask. In other words, the via and the trench are formed together by using a so-called dual damascene method.

The etching stop film 103 is made of an SiC-based material such as SiCN or the like, and a thickness thereof is within a range from about 20 nm to about 100 nm. Further, a low-k film such as an SiCO-based film or the like may be employed as the interlayer insulating film 104 on which the trench etching of this embodiment is to be performed. The interlayer insulating film 104 may also be formed of a conventionally used material such as SiO₂ or the like. A thickness of the interlayer insulating film 104 is within a range from about 250 nm to 340 nm. TiN, for example, is used as a material forming the metal hard mask layer 105, and a thickness thereof is within a range from about 15 nm and to 45 nm. The BARC 106 is mainly made of an organic material, and a thickness thereof is within a range from about 20 nm to about 100 nm. An ArF resist, for example, is used as the photoresist film 107, and a thickness thereof is within a range from about 100 nm to about 400 nm.

When performing the trench etching, firstly, the gate valve 86 is opened and, then, the semiconductor wafer W of the aforementioned structure is loaded into the chamber 10 via the gateway 85 and then mounted on the susceptor 16. Further, a processing gas for etching the interlayer insulating film 103 is supplied at a specific flow rate from the processing gas supply source 66 into the gas diffusion chamber 40, and then into the chamber 10 via the gas passage holes 41 and the gas ejection ports 37. After an inside of the chamber 10 is exhausted by the gas exhaust unit 84, an inner pressure thereof is set to be a specific level within a range from about 2.7 Pa to about 200 Pa. Further, a temperature of the susceptor is set between about 20° C. and about 50° C. (for example, at 40° C.). A wafer temperature is set between about 20° C. and about 100° C. (for example, at 60° C.).

As for a processing gas for etching the interlayer insulating film 104 made of a low-k film, there may be used various gases, e.g., a fluorocarbon containing gas (CₓF_{y}) and the like. Typically, there is used a CF₄ single gas or a gaseous mixture of CF₄ gas and Ar gas, He gas or the like and, further, there may be used a gaseous mixture of C₄F₈ gas or C₅F₈ gas and Ar gas or O₂ gas.

Under the condition that the etching gas is introduced into the chamber 10 in this manner, the first high-frequency power supply 48 is made to apply a high frequency power for plasma generation to the upper electrode 34 at a predetermined intensity and, at the same time, the second high-frequency power supply 90 is made to apply a high frequency power for ion attraction to the lower electrode or susceptor 16 at a prescribed intensity. A given direct current voltage is applied to the upper electrode 34 by means of the variable direct current power supply 50. Furthermore, a direct current voltage for the electrostatic chuck 18 is applied to the electrode 20 of the electrostatic chuck 18 from the direct current power supply 22, thereby fixing the semiconductor wafer W to the susceptor 16.

The processing gas ejected through the gas ejection ports 37 of the electrode plate 36 of the upper electrode 34 is converted to a plasma in the midst of glow discharge generated between the upper electrode 34 and the lower electrode or susceptor 16 by the high frequency power. With radicals or ions generated in the plasma, the trench etching is performed on the interlayer insulating film 104 of the semiconductor wafer W by using the metal hard mask layer 105 as an etching mask thereof.

Inasmuch as an electric power of high frequency band (e.g., 10 MHz or more) is supplied to the upper electrode 34, it becomes possible to increase the density of the plasma in a desired state, which in turn makes it possible to form a high density plasma even under a lower pressure condition. Further, when the plasma is generated in this manner, a DC voltage of a specific polarity and level is applied from the variable DC power supply 50 to the upper electrode 34. Therefore, the plasma etching rate can be controlled and, hence, the trench etching can be performed with a high intra-surface uniformity.

As a result of the etching described above, a trench 109 is formed in the interlayer insulating film 104, as illustrated in FIG. 5. At this time, the partial via 108 is also partially etched, thus forming a via 108′ that reaches the etching stop film 103.

Thereafter, the via 108′ is penetrated by etching the etching stop film 103 under specific conditions. Further, a metal such as copper or the like is buried in the via 108′ and the trench 109 according to a preset method.

The following is an explanation of an etching rate control through a DC voltage application.

By applying a DC voltage to the upper electrode 34, a plasma is also generated by the applied DC voltage as well as the high frequency power. Therefore, a plasma density is increased and, hence, an etching rate is enhanced. To be specific, when a negative DC voltage is applied to the upper electrode 34, it is difficult for electrons to enter the upper electrode 34 and, thus, an annihilation of the electrons is suppressed. Further, when accelerated ions enter the upper electrode, the electrons escape from the upper electrode and accelerated to a high speed by a potential difference between the plasma potential and the applied voltage level. Therefore, a neutral gas is ionized (converted into a plasma), thereby increasing an electron density (plasma density).

Further, when the plasma has been formed, if a DC voltage is applied from the variable DC power supply 50 to the upper electrode 34 in forming a plasma, the plasma density in the central portion can be relatively increased for a plasma diffusion. Especially when an inner pressure of the chamber 10 is relatively high and an electronegative gas is used as an etching gas, the plasma density in the central portion of the chamber 10 tends to be decreased. However, by applying a DC voltage to the upper electrode 34 as described above, the plasma density in the central portion can be increased. Moreover, by adjusting a voltage level of the DC voltage, the etching rate can be controlled, which enables a uniform etching to be carried out.

Especially in case of the trench etching as described above, despite the fact that an intra-surface uniformity of etching depth is highly important, the etching depth cannot be controlled by forming the etching stop film or the like. However, although an extremely high intra-surface uniformity is required in the etching process, a desired etching uniformity can be obtained by controlling the applied DC voltage.

To realize this effectively, it is preferable that the DC voltage applied to the upper electrode 34 is within a range from about −400 V to about −1500 V.

When performing the plasma etching method of the present embodiment, the first task is to perform a trench etching on a test-purpose semiconductor wafer under given conditions by use of the plasma etching apparatus shown in FIG. 1. Thereafter, the semiconductor wafer is conveyed out of the plasma etching apparatus and is inspected by means of an inspection apparatus to thereby find, in advance, a direct current voltage value by which an etching uniformity can be obtained while forming the trench by the etching on the interlayer insulating layer. If an etching operation is carried out while applying a direct current voltage of the value thus found to the upper electrode, it is possible to rapidly perform the etching treatment under appropriate conditions. As the test-purpose semiconductor wafer noted above, use may be made of a first single sheet or first two or more sheets of wafer in a particular wafer lot.

Hereinafter, a result of examining actual effects of the method of the present invention will be described. First of all, an SiO₂ film was formed on a silicon substrate and, then, a blanket etching was performed under following conditions:

Pressure: 13.3 Pa (100 mTorr)

RF power (upper 60 MHz/lower 2 MHz): 300 W/300 W

DC voltage: −500 V, −600 V, −650 V

Processing gas:
C₄F₈ gas: 30 mL/min (sccm)
CF₄ gas: 40 mL/min (sccm)
N₂ gas: 90 mL/min (sccm)
Ar gas: 750 mL/min (sccm)
O₂ gas: 5 mL/min (sccm)

Time: 60 sec

Temperature:
susceptor: 60° C.
Wafer: 50° C.

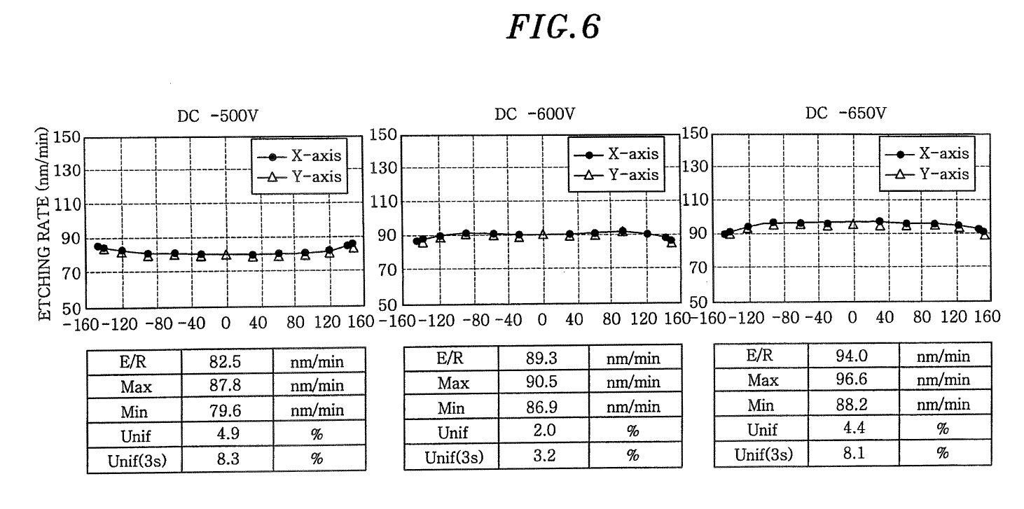

FIG. 6 shows an etching rate distribution obtained from the amount of film remaining after the etching. To be specific, when a DC voltage of −500 V was applied, an etching rate still tended to be higher in an edge portion than in a central portion. When a DC voltage of −600 V was applied, the etching rate was approximately uniform across the surface. When a DC voltage of −650 V was applied, the etching rate tended to be higher in the central portion than in the edge portion. From the above, it was verified that the etching rate can be controlled by applying a DC voltage to the upper electrode and adjusting a level thereof, and thus a uniform etching can be carried out. Further, as clear from FIG. 6, the etching rate was most uniform when a DC voltage of −600 V was applied. However, since an actual etching uniformity is also affected by a thickness distribution of a target film to be etched, a uniform etching rate may not ensure a uniform etching.

Thereafter, the blanket etching was performed under different conditions to be described as follows:

Pressure: 8.0 Pa (60 mTorr)

RF power (upper 60 MHz/lower 2 MHz): 300 W/150 W

DC voltage: −500 V, −600 V, −700 V

Processing gas:
C₄F₈ gas: 10 mL/min (sccm)
CF₄ gas: 112 mL/min (sccm)
Ar gas: 150 mL/min (sccm)
O₂ gas: 6 mL/min (sccm)

Time: 60 sec

Temperature:
susceptor: 60° C.
Wafer: 40° C.

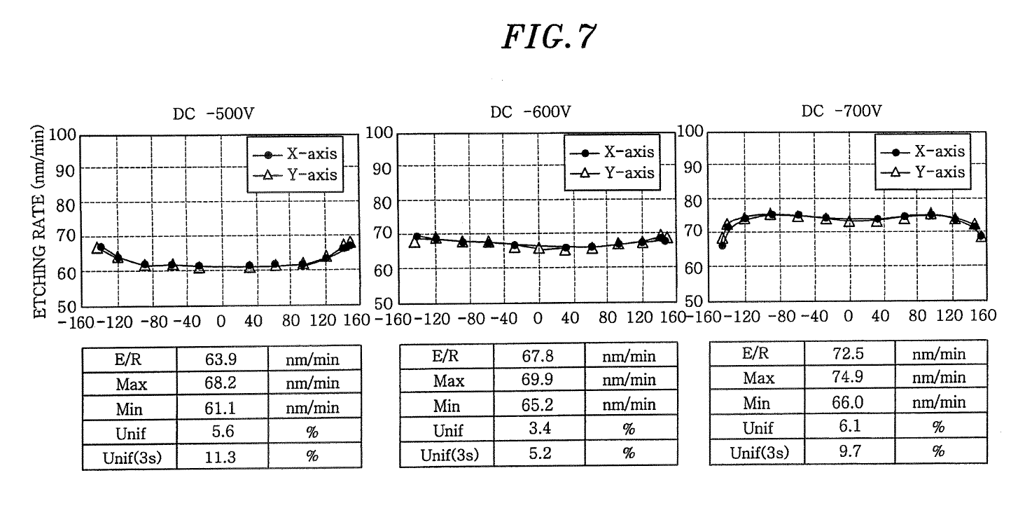

FIG. 7 shows an etching rate distribution obtained from the amount of a film remaining after the etching, which is similar to that described in FIG. 6. Specifically, when a DC voltage of −500 V was applied, the etching rate tended to be higher in an edge portion than in a central portion. When a DC voltage of −600 V was applied, the etching rate was fairly uniform due to an increase in the etching rate in the central portion. When a DC voltage of −700 V was applied, the etching rate tended to be higher in the central portion than in the edge portion. From the above, it was verified that the same results are obtained under the different conditions.

Next, as shown in FIG. 3, the partial via 108 was formed by etching the BARC 106 and the interlayer insulating film 104 by using the photoresist film 107 as the etching mask thereof. Thereafter, the BARC 106 and the photoresist film 107 were removed by an ashing, as illustrated in FIG. 4. Then, a trench etching was performed under following conditions:

Pressure: 13.3 Pa (100 mTorr)

RF power (upper 60 MHz/lower 2 MHz): 300 W/300 W

DC voltage: −500 V

Processing gas:
C₄F₈ gas: 30 mL/min (sccm)
CF₄ gas: 40 mL/min (sccm)
N₂ gas: 90 mL/min (sccm)
Ar gas: 750 mL/min (sccm)
O₂ gas: 5 mL/min (sccm)

Time: 100 sec

Temperature:
susceptor: 40° C.
Wafer: 60° C.

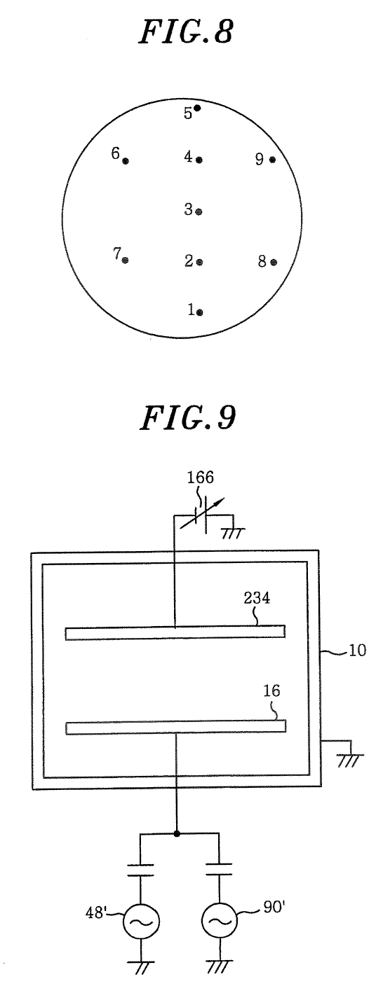

After the etching, a depth of the trench was measured in nine locations on the semiconductor wafer of FIG. 8 by using a scanning electron microscope (SEM). As a result, following trench depths were measured in each of the locations:

No. 1: 272 nm

No. 2: 264 nm

No. 3: 264 nm

No. 4: 272 nm

No. 5: 276 nm

No. 6: 272 nm

No. 7: 256 nm

No. 8: 274 nm

No. 9: 266 nm

As can bee seen from above, the trench etching depth has a variation of 20 nm, which is a great improvement compared with a conventional variation of 70 nm to 90 nm.

From the above, it was verified that, when a trench is formed by performing a plasma etching on a semiconductor wafer, the intra-surface uniformity of an etching rate can be achieved, and the intra-surface uniformity of a trench etching depth can be enhanced by applying a DC voltage to the upper electrode and controlling a level thereof.

Moreover, the present invention can be variously modified without being limited to the aforementioned embodiment. For example, although the dual damascene structure has been proposed in the aforementioned embodiment, a conventional damascene structure can also be employed. Further, the present invention can be also applied in forming a trench in a film other than the interlayer insulating film. Moreover, the present invention can also be applied to a case of forming a trench directly on a substrate without being limited to a case of forming a trench on a film on the substrate.

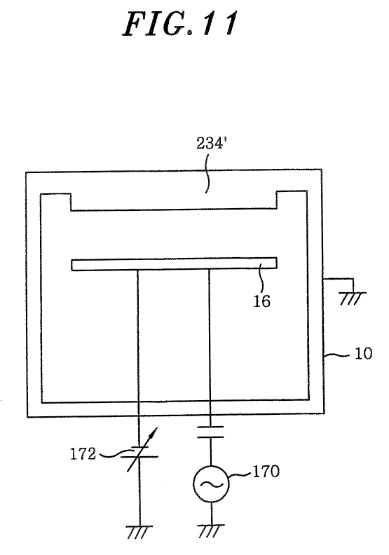

Furthermore, the apparatus for implementing the present invention is not limited to the one shown in FIG. 1. Alternatively, it may be possible to use a variety of other apparatuses as set forth below. For instance, it is possible to employ a plasma etching apparatus of the type applying two kinds of frequencies to a lower electrode as shown in FIG. 9, in which a high frequency power of, e.g., 60 MHz, for plasma generation is applied to the lower electrode from a first high-frequency power supply 48′ and a high frequency power of, e.g., 2 MHz, for ion attraction is applied to the lower electrode from a second high-frequency power supply 90′. The same advantageous effects as in the foregoing embodiments can be obtained by connecting a variable direct current power supply 166 to an upper electrode 234 and applying a given direct current voltage thereto as illustrated in FIG. 11.

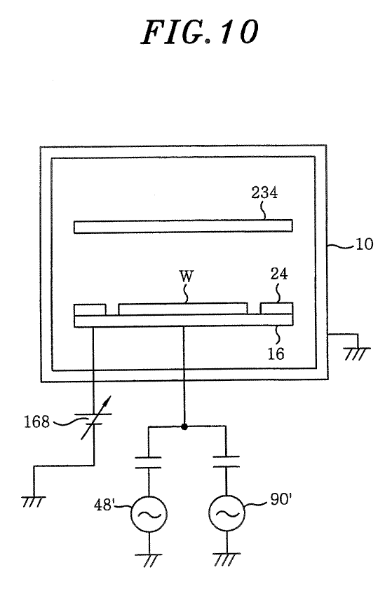

In this case, it may be possible that, as shown in FIG. 10, a direct current power supply 168 is connected to the lower electrode or susceptor 16 to thereby apply a direct current voltage to the susceptor 16.

Moreover, it is possible to employ a plasma etching apparatus of the type as shown in FIG. 11, wherein an upper electrode 234′ is grounded via the chamber 10 and a high-frequency power supply 170 is connected to the lower electrode or susceptor 16 so that the high-frequency power supply 170 can apply a high frequency power of, e.g., 13.56 MHz, for plasma generation. In this case, the same advantageous effects as in the foregoing embodiments can be obtained by connecting a variable direct current power supply 172 to the lower electrode or susceptor 16 and applying a given direct current voltage thereto as illustrated in FIG. 13.

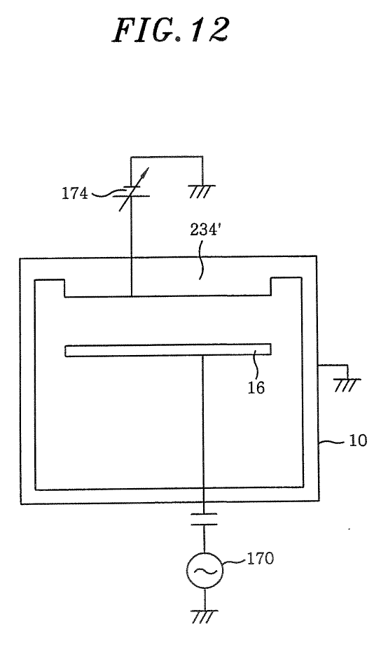

Alternatively, as illustrated in FIG. 12, a variable direct current power supply 174 may be connected to the upper electrode 234′ in the same plasma etching apparatus as shown in FIG. 11, wherein the upper electrode 234′ is grounded via the chamber 10 and the high-frequency power supply 170 is connected to the lower electrode or susceptor 16 so that the high-frequency power supply 170 can apply a high frequency power for plasma generation.

While the invention has been shown and described with respect to the embodiment, it will be understood by those skilled in the art that various changes and modification may be made without departing from the scope of the invention as defined in the following claims.

What is claimed is:

1. A plasma etching method for forming a trench on a substrate or on a film formed on the substrate, comprising:
an substrate arranging step of arranging the substrate on which the trench is to be formed in a processing chamber having therein a first and a second electrode disposed to face each other vertically;
a processing gas introducing step of introducing a processing gas for etching into the processing chamber;
a plasma generating step of generating a plasma by applying a high frequency electric power to either of the first and the second electrode; and
a DC voltage applying step of applying a DC voltage to said either of the electrodes.

2. The plasma etching method of claim 1, wherein the DC voltage is within a range from about −400 V to about −1500 V.

3. The plasma etching method of claim 1, wherein the trench is formed in an interlayer insulating film formed on the substrate.

4. The plasma etching method of claim 2, wherein the trench is formed in an interlayer insulating film formed on the substrate.

5. The plasma etching method of claim 3, wherein the trench is formed after a via is formed in the interlayer insulating film.

6. The plasma etching method of claim 4, wherein the trench is formed after a via is formed in the interlayer insulating film.

7. The plasma etching method of claim 1, wherein a specific DC voltage level for securing a desired intra-surface etching uniformity on a test object is obtained in advance, and the specific DC voltage level is applied to said either of the electrodes in the DC voltage applying step.

8. The plasma etching method of claim 2, wherein a specific DC voltage level for securing a desired intra-surface etching uniformity on a test object is obtained in advance, and the specific DC voltage level is applied to said either of the electrodes in the DC voltage applying step.

9. The plasma etching method of claim 1, wherein the first electrode is an upper electrode, the second electrode is a lower electrode for mounting thereon an object to be processed, and the high frequency electric power for generating the plasma and the DC voltage are applied to the first electrode.

10. The plasma etching method of claim 2, wherein the first electrode is an upper electrode, the second electrode is a lower electrode for mounting thereon an object to be processed, and the high frequency electric power for generating the plasma and the DC voltage are applied to the first electrode.

11. The plasma etching method of claim 7, wherein the first electrode is an upper electrode, the second electrode is a lower electrode for mounting thereon an object to be processed, and the high frequency electric power for generating the plasma and the DC voltage are applied to the first electrode.

12. The plasma etching method of claim 8, wherein the first electrode is an upper electrode, the second electrode is a lower electrode for mounting thereon an object to be processed, and the high frequency electric power for generating the plasma and the DC voltage are applied to the first electrode.

13. The plasma etching method of claim 9, wherein a high frequency electric power for attracting ions is applied to the second electrode.

14. The plasma etching method of claim 10, wherein a high frequency electric power for attracting ions is applied to the second electrode.

15. The plasma etching method of claim 11, wherein a high frequency electric power for attracting ions is applied to the second electrode.

16. The plasma etching method of claim 12, wherein a high frequency electric power for attracting ions is applied to the second electrode.

17. A computer-readable storage medium for storing therein a computer-executable control program, wherein, when the control program is being executed, a computer is made to control a plasma processing apparatus to perform the plasma etching method described in claim 1.

18. A computer-readable storage medium for storing therein a computer-executable control program, wherein, when the control program is being executed, a computer is made to control a plasma processing apparatus to perform the plasma etching method described in claim 2.

19. A computer-readable storage medium for storing therein a computer-executable control program, wherein, when the control program is being executed, a computer is made to control a plasma processing apparatus to perform the plasma etching method described in claim 7.

20. A computer-readable storage medium for storing therein a computer-executable control program, wherein, when the control program is being executed, a computer is made to control a plasma processing apparatus to perform the plasma etching method described in claim 9.
